(19) United States
(12) Patent Application Publication
(10) Pub. No.: US 2009/0108268 A1
(43) Pub. Date: Apr. 30, 2009

(54) COMPOSITE LIGHT-EMITTING-DIODE PACKAGING STRUCTURE

(76) Inventor: Pai-Ling Sung, Taipei City (TW)

Correspondence Address: RABIN & Berdo, PC, 1101 14TH STREET, NW, SUITE 500, WASHINGTON, DC, 20005, US

(21) Appl. No.: 11/926,396

(22) Filed: Oct. 29, 2007

(51) Int. Cl. H01L 33/00

(52) U.S. Cl. 257/88; 257/99; 257/E33.058

(57) ABSTRACT

A composite light-emitting-diode (LED) packaging structure having oppositely arranged chips comprises a first substrate with a first surface and a second surface, a second substrate with a first surface and a second surface, a first LED chip on the first surface of the first substrate, and a second LED chip on the first surface of the second substrate. The second surface of the second substrate and the second surface of the first substrate are packaged integrally in contact.

### BACKGROUND

1. Field of the Invention

The invention relates to a light-emitting-diode (LED) packaging structure and in particular to a composite light-emitting-diode packaging structure.

2. Related Art

Presently, the white light light-emitting-diode is the most promising LED-based product used for illumination, and it has great potential for development in the illumination device industry. Compared with conventional tungsten filament light bulb emitting incandescent lights and fluorescent lamps, the LED has the benefit of being small in size (so that a plurality of multiple-type LEDs can be integrally packaged together into one piece), having low heat dissipation (with no heat radiation), lower power consumption (low actuation current and voltage), long service life span (more than 10,000 hours), fast response (so that it can be operated at high frequencies), environmental protection (shock resistant, impact resistant, recyclable and non-polluting), and flat packaging so that it can be made to have light weight, thin profile, and compact size. It does not have the disadvantages of being brittle, having high power consumption of the incandescent light bulb and mercury pollution, as with the disposable fluorescent lamp. As such it is regarded as a potential replacement for the conventional illumination device over the next 10 years.

Utilizing the incandescent tungsten filament light bulb or LED chip as the light source for a lamp can hardly achieve all angle omni-directional (approximately 360°) illumination without having the so-called “dark corners.” Thus there is always some place such as behind of light source where it is difficult to achieve direct and sufficient illumination. Therefore, for application as the light source for a lamp or light post, for example, for lamp of the individual light post in a park, there may always be some place or dark corner where it is not illuminated sufficiently, thus resulting in insecurity and inconvenience for people walking around in its vicinity. One way to solve this problem is to provide more lamps for light posts to eliminate the so-called illumination dark corners. However, by doing so, the costs of equipment, installation and electricity would increase significantly.

On the other hand, when the incandescent tungsten filament light bulb or LED chip is used as the light source for a lamp, once the tungsten filament is burned out or the chip fails, then the lamp fails in its function of illumination, and that necessitates the replacement of the light bulb or the LED chip. More seriously, if the lamp is located in some inconvenient place, for example, on ceilings, then its replacement causes a lot of difficulty for the user. Furthermore, if it is utilized as a light source in emergency lighting equipment, the lack of maintenance and replacement will result in it losing the function of emergency lighting when an accident does occur.

Therefore, the research and development of a light source that is capable of providing all-angle omni-directional illumination and reducing the frequency of replacement is the most important task in this field.

### SUMMARY OF THE INVENTION

The object of the invention is to provide a composite LED packaging structure that can solve the problems of the prior art by making use of the combined opposite arrangement of the upper and lower LED chip package structures, thus achieving approximately 360° illumination. Furthermore, through the parallel connection and/or other appropriate circuit design, the upper and lower LED chips can be controlled to emit lights simultaneously or separately, so that when it is utilized as the light source for a lamp, the failure of one of the upper and lower LED chips will not cause the lamp to lose its function of illumination.

Therefore, to achieve the above-mentioned objective, the invention provides a composite LED packaging structure, including: a first substrate having a first surface and a second surface; a second substrate having a first surface and a second surface; a first LED chip provided on the first surface of the first substrate; and a second LED chip provided on the first surface of the second substrate. The second surface of the second substrate and the second surface of the first substrate are packaged integrally in contact.

Alternatively, to achieve the above-mentioned objective, the invention provides a composite LED packaging structure, including: a substrate having a first surface and a second surface; a first LED chip provided on the first surface of the substrate; and a second LED chip provided on the second surface of the substrate.

The above-mentioned substrates may all be transparent substrates.

In the above-mentioned structure, the upper LED transparent chip can be electrically connected to the upper substrate through a connection wire, and the lower LED transparent chip can be electrically connected to the lower substrate through a connection wire.

In addition, the upper LED transparent chip can be enclosed with a transparent cover body; and the lower LED transparent chip can be enclosed with a transparent cover body.

Further scope of the applicability of the invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The invention will become more fully understood from the detailed description given below, which is for illustration only and thus is not limitative of the invention.

FIG. 1 is a schematic diagram of the composite LED packaging structure before packaging according to a preferred embodiment of the invention;

FIG. 2 is a schematic diagram of the composite LED packaging structure after packaging according to a preferred embodiment of the invention; and

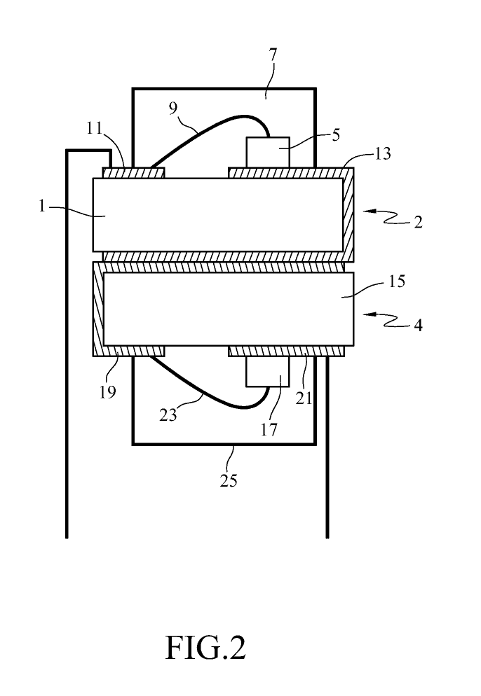

FIG. 3 is a schematic diagram of the composite LED packaging structure after packaging according to another preferred embodiment of the invention.

### DETAILED DESCRIPTION OF THE INVENTION

The purpose, construction, features, and functions of the invention can be appreciated and understood more thoroughly through the following detailed description with reference to the attached drawings.

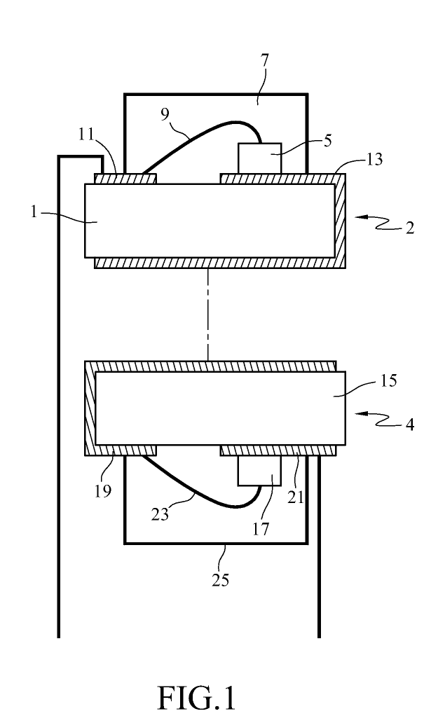

The invention provides a composite LED packaging structure. Refer to FIGS. 1 & 2, which show schematic diagrams of the composite LED packaging structure before and after packaging according to a preferred embodiment of the invention.

As shown in FIGS. 1 & 2, the composite LED packaging structure includes two LED package portions: an upper LED package structure 2, and a lower LED package structure 4. The upper LED packaging structure 2 and the lower LED package structure 4 are packaged in a back-to-back manner.

The structure and functions of its various components are described as follows:

The upper LED package structure 2 includes: an upper substrate 1; an upper LED chip 5 provided on the upper substrate 1 that is enclosed with a cover body 7. The cover body 7 is made of light transmitting filling material, so that the light emitted by the upper LED chip 5 may transmit through.

The upper substrate 1 can be a metal substrate, a non-metal substrate or a transparent substrate, and is provided with a connection pad 11 or electric pattern 13 on its outer surface for electrically connecting to the LED chip 5. The respective connection pads 11 or electrical patterns 13 are not connected to each other and are in an insulated state. The connection wire 9 may be coated with a conductive glue (not shown), and is connected between the connection pad 11 and the LED chip 5. To facilitate welding and adhesion, the conduction glue is usually made of one of the following: gold, silver, tin, chromium, nickel, or an alloy thereof. Since gold is much more expensive and the effects of its reflection are unsatisfactory, it is not used very often.

The upper LED chip 5 can be any commercial available chip of various colors of the prior art.

The lower LED packaging structure 4 includes: a lower substrate 15; a lower LED chip 17 provided on the substrate 15 and enclosed with a cover body 25. The cover body 25 is made of light transmitting filling material, so that the light emitted by the lower LED chip 17 can transmit through.

The lower substrate 15 can be a metal substrate, a non-metal substrate or a transparent substrate, and is provided with the connection pad 19 or electrical pattern 21 on its outer surface for electrically connecting to the LED chip 17. The respective connection pads 19 and electrical patterns 21 are not connected to each other and are in an insulated state. The connection wire 23 may be coated with a conductive glue (not shown), and is connected between the connection pad 19 and the LED chip 17. The lower substrate 15 includes another side of the LED chip 17 and is bonded onto the backside of the upper substrate 1.

To facilitate welding and adhesion, the conduction glue is usually made of one of the following: gold, silver, tin, chromium, nickel, or an alloy thereof. Since gold is much more expensive and the effects of its reflection are un-satisfactory, so it is not used very often.

The lower LED chip 17 can be any commercially available chip of various colors of the prior art.

The upper and lower cover bodies 7 and 25 are made of light transmitting material by means of a low pressure modeling technique or encapsulated technique, as such providing the protection function of the cover body 7.

Moreover, the light transmitting material mentioned above may be epoxy resin.

In addition, the upper LED package structure 2 and lower LED package structure 4 of the composite LED packaging structure may be the same or different types of LED package structure; the key point is that the LED package structure must be capable of emitting light on one side of the substrate.

Furthermore, though two substrates are used in the above description as an example, in practice the two substrates may be reduced to one. That is, only one substrate is provided and the LED chips are provided on both sides of the same substrate.

Finally, the bonding process of the upper and lower LED package structures is described in detail as follows.

Upon finishing the assembly of the upper and lower LED package structures 2 and 4, the lower LED structure 4 is aligned with the upper LED structure 2 and bonded onto it with their substrates in a back-to-back position, as such realizing the composite LED packaging structure.

In this structure, the bonding of the upper and lower substrates 1 and 15 are made through the connection pads 11 and 19 respectively.

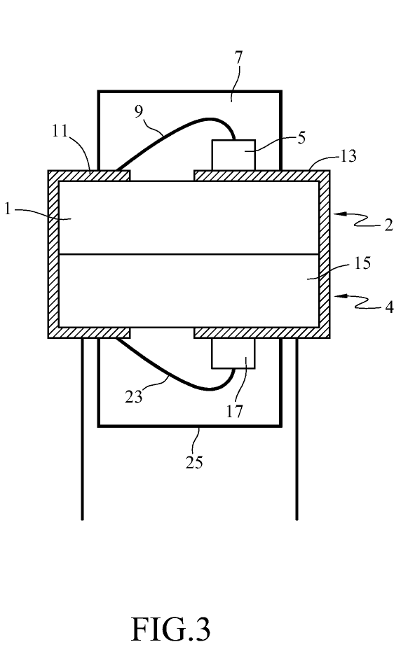

As mentioned above, the circuit design of the upper and lower LED package structures 2 and 4 may be realized according to actual requirements, as shown in FIG. 3, so the circuit of the upper LED package structure 2 and that of the lower LED package structure 4 may be connected in parallel, so that in case one of the LED chips fails, the other LED chip of the composite LED packaging structure may still function normally and emit light. As such, when this composite LED packaging structure is utilized in an illumination device, it can still maintain illumination even if one of the chips fails. Moreover, in addition to the parallel connection circuit design between the upper and lower LED package structures 2 and 4 so that they both emit light at the same time, other types of circuit designs may be utilized depending on actual requirements so that they may emit light at the same time or separately. The circuit design mentioned above is well known to those familiar with the art so will not be described here.

According to the above description, the composite LED packaging structure of the invention can be used to achieve illumination at nearly 360° through the upper and lower opposite direction packaged LED chips. Thus, the device of the invention may be applied to lamps of illumination devices to realize omni-directional all-angle illumination.

In addition, through the parallel circuit design of the upper and lower LED package structures or through their separate circuit designs, only the light of the upper LED package structure is emitted or only the light of the lower LED package structure is emitted, so that even if one of the two LED chips should fail, the illumination device can still maintain illumination.

Summing up the above, through the combination of the two LED package structures into a back-to-back opposite direction arrangement, all-angle omni-directional illumination can be achieved, and the possibility of losing illumination when one of the LED package structures fails can be avoided.

Knowing the invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A composite light-emitting-diode packaging structure, comprising:
a first substrate, having a first surface and a second surface;
a second substrate, having a first surface and a second surface;
a first LED chip, provided on said first surface of said first substrate; and
a second LED chip, provided on said first surface of said second substrate;
wherein, said second surface of said second substrate and said second surface of said first substrate are packaged integrally in contact.

2. The composite light-emitting-diode (LED) packaging structure of claim 1, wherein said first LED chip is electrically connected to said first substrate through a connection wire.

3. The composite light-emitting-diode (LED) packaging structure of claim 1, wherein said second LED chip is electrically connected to said second substrate through a connection wire.

4. The composite light-emitting-diode (LED) packaging structure of claim 1, wherein said first LED chip is enclosed with a transparent cover body.

5. The composite light-emitting-diode (LED) packaging structure of claim 1, wherein said second LED chip is enclosed with a transparent cover body.

6. The composite light-emitting-diode (LED) packaging structure of claim 1, wherein said first substrate and said second substrate are both transparent substrates.

7. A composite light-emitting-diode (LED) packaging structure, comprising:
a substrate, having a first surface and a second surface;
a first LED chip, provided on said first surface of said substrate; and
a second LED chip, provided on said second surface of said substrate.

8. The composite light-emitting-diode (LED) packaging structure of claim 7, wherein said first LED chip is electrically connected to said substrate through a connection wire.

9. The composite light-emitting-diode (LED) packaging structure of claim 7, wherein said second LED chip is electrically connected to said substrate through a connection wire.

10. The composite light-emitting-diode (LED) packaging structure of claim 7, wherein said substrate is a transparent substrate.
